(19) United States
(12) Patent Application Publication
(10) Pub. No.: US 2026/0304963 A1
(43) Pub. Date: Oct. 1, 2026

(54) SEMICONDUCTOR DEVICE

(71) Applicant: ROHM CO., LTD., Kyoto-shi (JP)

(72) Inventor: Kohei MURASAKI, Kyoto-shi (JP)

(73) Assignee: ROHM CO., LTD., Kyoto-shi (JP)

(21) Appl. No.: 19/679,862

(22) Filed: May 18, 2026

Related U.S. Application Data
(63) Continuation of application No. PCT/JP2024/041144, filed on Nov. 20, 2024.

(30) Foreign Application Priority Data
Nov. 24, 2023 (JP) 2023-199321

(51) Int. Cl. H10D 89/60; H10D 8/00; H10D 12/00; H10D 84/00

(52) U.S. Cl. CPC H10D 89/60; H10D 8/411; H10D 12/481; H10D 84/161

(57) ABSTRACT

A semiconductor device includes a semiconductor substrate, a transistor, a temperature sensing diode, an insulating layer formed above the temperature sensing diode, a diode pad arranged at a position separated from the temperature sensing diode, embedded interconnect, and a first transistor pad. The semiconductor substrate includes a substrate upper surface and a substrate lower surface opposite the substrate upper surface. The transistor is formed above the substrate upper surface of the semiconductor substrate. The temperature sensing diode is formed above the substrate upper surface of the semiconductor substrate. The embedded interconnect is embedded in the insulating layer to connect the temperature sensing diode and the diode pad. The first transistor pad is electrically connected to the transistor and includes a portion formed above the temperature sensing diode such that the insulating layer is sandwiched between the portion and the temperature sensing diode.

### CROSS-REFERENCE TO RELATED APPLICATIONS

This application is a continuation of, and claims the benefit of priority from International Application No. PCT/JP2024/041144, filed on Nov. 20, 2024, which claims the benefit of priority from Japanese Patent Application No. 2023-199321, filed on Nov. 24, 2023, the entire contents of each of which are incorporated herein by reference.

### BACKGROUND

### 1. Field

The present disclosure relates to a semiconductor device.

### 2. Description of Related Art

A switching element, such as an insulated gate bipolar transistor (IGBT) used in an in-vehicle inverter device, is switched at high speed between a state in which current flows and a state in which current does not flow, and therefore tends to increase in temperature. To ensure that the temperature of the switching element does not exceed its operable range, the switching element may be provided with a temperature sensing diode for detecting the temperature of the switching element. JP2017-103272A discloses a switching element provided with a temperature sensing diode.

### BRIEF DESCRIPTION OF DRAWINGS

FIG. 1 is a plan view of a semiconductor device in accordance with an embodiment.

FIG. 2 is a plan view showing the semiconductor device of FIG. 1 without a protective insulating film.

FIG. 3 is a cross-sectional view taken along line 3-3 in FIG. 1.

FIG. 4 is a cross-sectional view taken along line 4-4 in FIG. 1.

FIG. 5 is a cross-sectional view taken along line 5-5 in FIG. 2.

FIG. 6 is an enlarged view showing a cathode pad in the semiconductor device of FIG. 1.

FIG. 7 is a cross-sectional view taken along line 7-7 in FIG. 6.

FIG. 8 is a plan view showing conductive members bonded to the semiconductor device of FIG. 1.

FIG. 9 is a plan view showing a conductive member bonded to the semiconductor device of FIG. 1.

FIG. 10 is a cross-sectional view showing a modified example of the semiconductor device.

### DETAILED DESCRIPTION

Embodiments of a semiconductor device will now be described with reference to the accompanying drawings.

Elements in the figures are illustrated for simplicity and clarity and have not necessarily been drawn to scale. To aid understanding, hatching lines may not be shown in the cross-sectional drawings. The accompanying drawings illustrate exemplary embodiments in accordance with the present disclosure and are not intended to limit the present disclosure.

This detailed description provides a comprehensive understanding of exemplary methods, apparatuses, and/or systems in accordance with the present disclosure. Exemplary embodiments may have different forms, and are not limited to the examples described.

### Planar Layout of Semiconductor Device

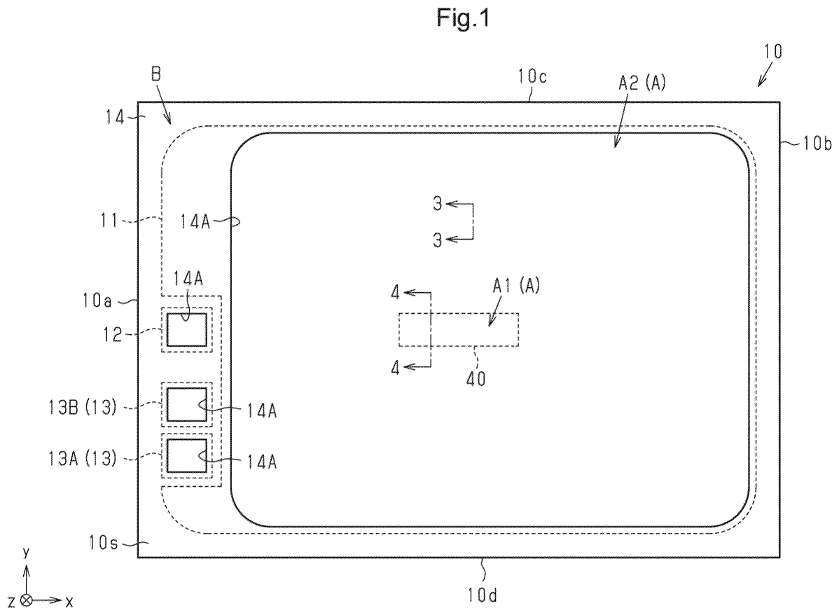

FIG. 1 is a schematic plan view of an exemplary semiconductor device 10 according to one embodiment.

The semiconductor device 10 includes a transistor 20 and a temperature sensing diode 40 that detects the temperature of the semiconductor device 10. The transistor 20 and the temperature sensing diode 40 are mounted on the same chip. The transistor 20 is, for example, an insulated gate bipolar transistor (IGBT). The semiconductor device 10 is used as, for example, a switching element in an inverter device for a vehicle. In this case, for example, a current between 5 A and 1000 A, inclusive, flows through the semiconductor device 10. The transistor 20 and the temperature sensing diode 40 will be described in detail later.

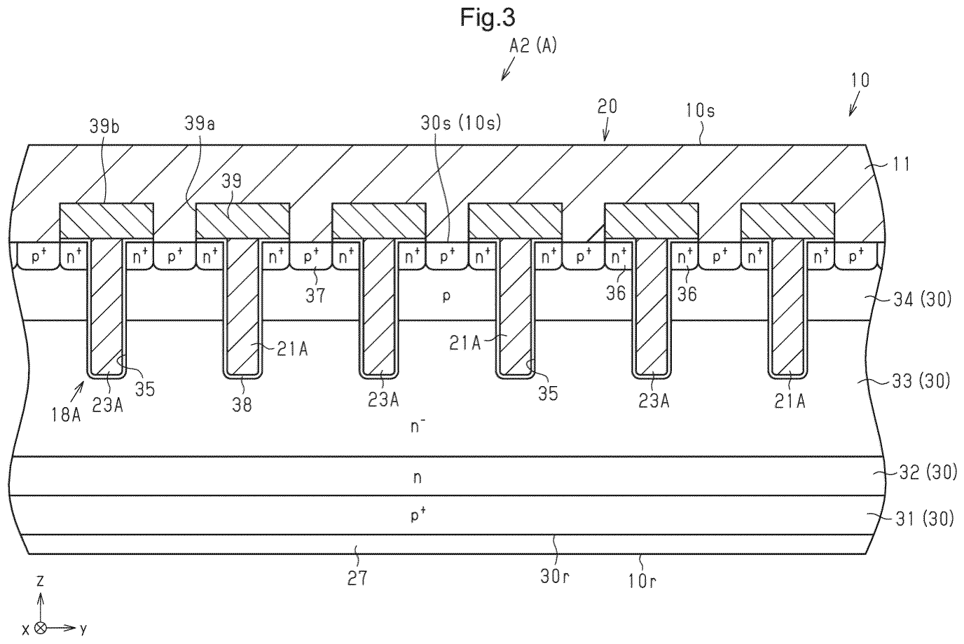

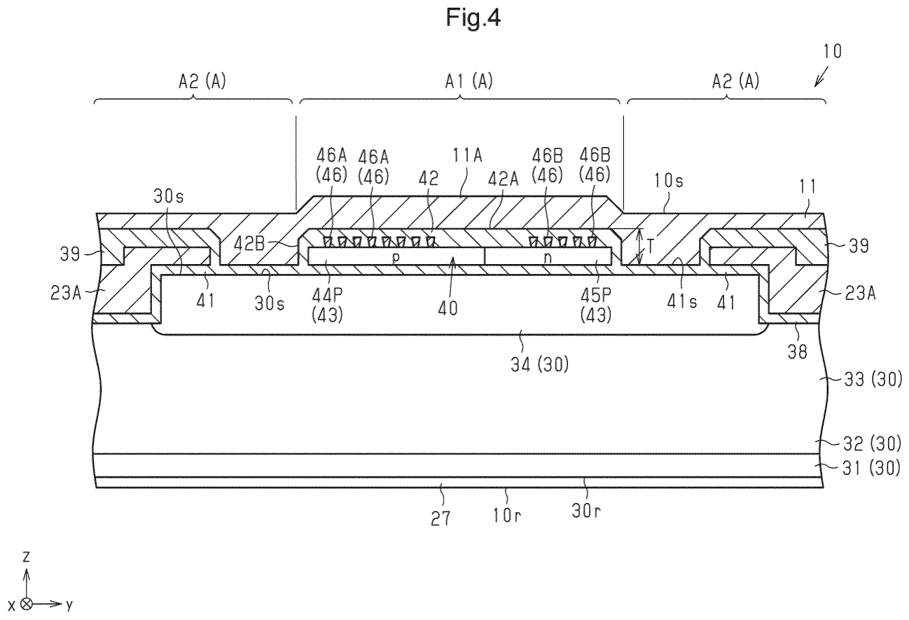

As shown in FIG. 1, the semiconductor device 10 has, for example, the form of a quadrilateral plate. The semiconductor device 10 includes a device upper surface 10s, a device lower surface 10r (refer to FIGS. 3 and 4) opposite the device upper surface 10s, and four device side surfaces 10a to 10d formed between the device upper surface 10s and the device lower surface 10r. For example, the device side surfaces 10a to 10d connect the device upper surface 10s and the device lower surface 10r and are orthogonal to both the device upper surface 10s and the device lower surface 10r. The device upper surface 10s is, for example, rectangular.

In the description hereafter, the device upper surface 10s and the device lower surface 10r face a direction referred to as the z-direction. The z-direction may also be referred to as the height direction of the semiconductor device 10. Two directions that are orthogonal to each other and orthogonal to the z-direction are referred to as the x-direction and the y-direction. In the present embodiment, the device side surfaces 10a and 10b define the two end surfaces of the semiconductor device 10 in the x-direction, and the device side surfaces 10c and 10d define the two end surfaces of the semiconductor device 10 in the y-direction. Unless otherwise indicated, the term “plan view” as used in this specification will refer to a view of the semiconductor device 10 taken from above in the z-direction. Plan view refers to a view taken in a thickness direction of a semiconductor substrate 30, which will be described later.

The semiconductor device 10 includes an active region A defined by a central portion of the semiconductor device 10, and a peripheral region B defined by a peripheral portion of the semiconductor device 10, in plan view. The active region A is where the transistor 20 or the temperature sensing diode 40 is formed. The peripheral region B is where neither the transistor 20 nor the temperature sensing diode 40 is formed. The peripheral region B surrounds the active region A in plan view, and includes strips extending along the edges of the active region A. The peripheral region B is looped and surrounds the active region A in plan view. The term “looped” as used in the present disclosure may refer to any closed shape that is endless and continuous. A “looped” shape includes, but is not limited to, a circular shape, an elliptical shape, and a polygonal shape with sharp or rounded corners.

The active region A includes a diode region A1 where the temperature sensing diode 40 is formed, and a transistor region A2 where the transistor 20 is formed. The diode region A1 is located in the central portion of the active region A in plan view. The transistor region A2 surrounds the diode region A1 in plan view. The transistor region A2 is looped and surrounds the diode region A1 in plan view. The diode region A1 and the transistor 20 do not overlap each other and are separated from each other in plan view.

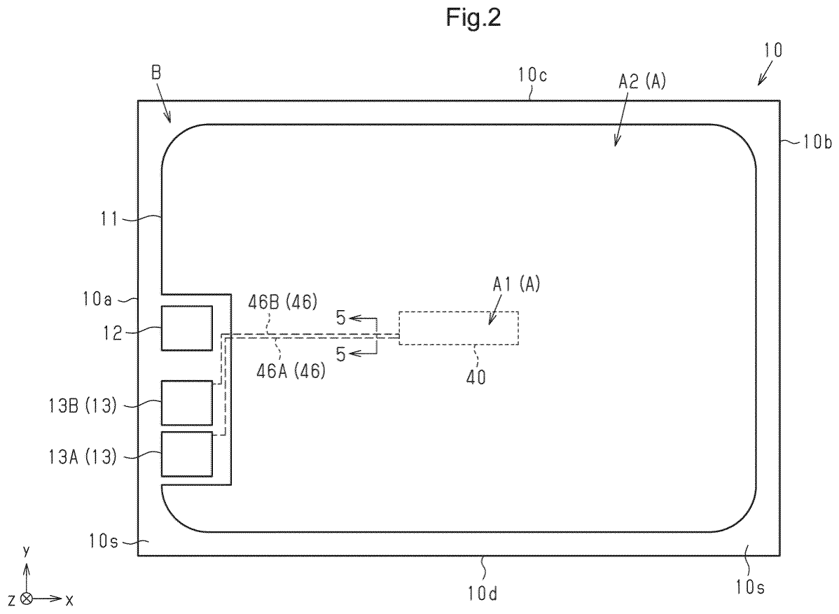

FIG. 2 shows the layout of electrode pads in the semiconductor device 10. FIG. 2 is a plan view showing the semiconductor device 10 without a protective insulating film 14, which will be described later.

As shown in FIG. 2, a first transistor pad 11 and a second transistor pad 12, which are electrically connected to the transistor 20, and diode pads 13, which are electrically connected to the temperature sensing diode 40, are arranged on the device upper surface 10s of the semiconductor device 10. The first transistor pad 11, the second transistor pad 12, and the diode pads 13 may each be formed by, for example, any conductive material including at least one of copper (Cu), aluminum (Al), an AlCu alloy, tungsten (W), titanium (Ti), and titanium nitride (TiN).

The first transistor pad 11 is an electrode pad electrically connected to base contact regions 37 of the transistor 20. The first transistor pad 11 overlaps the transistor 20, which is arranged in the transistor region A2, in plan view. The first transistor pad 11 covers the entire active region A in the device upper surface 10s. In one example, the first transistor pad 11 is formed over the transistor 20 and the temperature sensing diode 40. The first transistor pad 11 covers the entire diode region A1 in plan view. Accordingly, the first transistor pad 11 covers the entire temperature sensing diode 40.

The first transistor pad 11 may be formed above at least part of the active region A. Therefore, the position of the first transistor pad 11 on the device upper surface 10s of the semiconductor device 10 is not limited to the position described above. For example, the first transistor pad 11 may be shaped to cover only part of the temperature sensing diode 40 in plan view. Further, the first transistor pad 11 may be shaped to expose the temperature sensing diode 40. That is, the first transistor pad 11 may be formed above only the transistor region A2. In the example described hereafter, the first transistor pad 11 is formed over the transistor 20 and the temperature sensing diode 40. Further, the first transistor pad 11 covers the entire temperature sensing diode in plan view.

The second transistor pad 12 is an electrode pad electrically connected to the electrode material in gate trenches 23A of the transistor 20. The second transistor pad 12 is arranged at a position separated from the transistor 20 in plan view.

The diode pads 13 include an anode pad 13A and a cathode pad 13B. The anode pad 13A is an electrode pad electrically connected to a first semiconductor region 44P of the temperature sensing diode 40. The cathode pad 13B is an electrode pad electrically connected to a second semiconductor region 45P of the temperature sensing diode 40. The diode pads 13 are arranged at positions separated from the temperature sensing diode 40 in plan view. The first semiconductor region 44P and the second semiconductor region 45P respectively correspond to an anode region 44P and a cathode region 45P.

The anode pad 13A and the cathode pad 13B, which are the diode pads 13, and the second transistor pad 12 are arranged on the device upper surface 10s in the peripheral region B. The anode pad 13A, the cathode pad 13B, and the second transistor pad 12 are arranged in the peripheral region B near the same device side surface (e.g., the device side surface 10a). In other words, the second transistor pad 12, the anode pad 13A and the cathode pad 13B are arranged in a portion of the peripheral region B located near the same device side surface (e.g., the device side surface 10a).

In one example, the cathode pad 13B is adjacent to the second transistor pad 12 in the y-direction. The cathode pad 13B and the second transistor pad 12 are arranged next to each other in the y-direction in plan view. The anode pad 13A is adjacent to the cathode pad 13B in the y-direction. The anode pad 13A and the cathode pad 13B are arranged next to each other in the y-direction in plan view.

The second transistor pad 12, the cathode pad 13B, and the anode pad 13A may be formed anywhere in the peripheral region B. Therefore, the positions of the second transistor pad 12, the cathode pad 13B, and the anode pad 13A in the device upper surface 10s of the semiconductor device 10 are not limited to the positions described above. In one example described hereafter, the cathode pad 13B, the anode pad 13A, and the second transistor pad 12 are all arranged near the device side surface 10a in the peripheral region B.

As shown in FIG. 1, the protective insulating film 14 is arranged on the device upper surface 10s. The protective insulating film 14 is an organic protective film for protecting the semiconductor device 10 and is formed from, for example, a material including polyimide (PI). The protective insulating film 14 includes openings 14A that independently expose a central portion of each of the first transistor pad 11, the second transistor pad 12, the cathode pad 13B, and the anode pad 13A. The openings 14A in the protective insulating film 14 are separated from one another in plan view. The protective insulating film 14 covers the peripheral portion of each of the first transistor pad 11, the second transistor pad 12, the cathode pad 13B, and the anode pad 13A.

### Configuration of the Transistor

FIG. 3 is a cross-sectional view taken along line 3-3 in FIG. 1 and shows one example of the semiconductor device 10 in the transistor region A2.

The semiconductor device 10 includes the semiconductor substrate 30. The semiconductor substrate 30 is formed from a material containing, for example, an n⁻-type silicon (Si). The semiconductor substrate 30 has a thickness of, for example, between 50 μm and 200 μm, inclusive.

The semiconductor substrate 30 includes a substrate upper surface 30s and a substrate lower surface 30r facing opposite directions in the z-direction. The semiconductor substrate 30 has a structure in which a p⁺-type collector layer 31, an n-type buffer layer 32, and an n⁻-type drift layer 33 are stacked in order from the substrate lower surface 30r to the substrate upper surface 30s. A collector electrode 27 is formed on the substrate lower surface 30r. The collector electrode 27 is formed over substantially the entire substrate lower surface 30r. The surface of the collector electrode 27 opposite the collector layer 31 defines the device lower surface 10r of the semiconductor device 10.

The collector layer 31 is doped with a p-type dopant, such as boron (B) or aluminum (Al). The collector layer 31 has a dopant concentration of, for example, between 1×10¹⁵ cm⁻³ and 2×10¹⁹ cm⁻³, inclusive.

The buffer layer 32 and the drift layer 33 are doped with an n-type dopant, such as nitrogen (N), phosphorus (P), or arsenic (As). The buffer layer 32 has a dopant concentration of, for example, between 1×10¹⁵ cm⁻³ and 5×10¹⁷ cm⁻³, inclusive. The drift layer 33 has a dopant concentration lower than that of the buffer layer 32, the dopant concentration of the drift layer 33 being, for example, between 1×10¹³ cm⁻³ and 5×10¹⁴ cm⁻³, inclusive.

A p-type base region 34 is formed on the upper surface of the drift layer 33. The base region 34 is formed over substantially the entire substrate upper surface 30s. The base region 34 has a dopant concentration of, for example, between 1×10¹⁶ cm⁻³ and 1×10¹⁸ cm⁻³, inclusive. The base region 34 has a thickness of, for example, between 1.0 μm and 3.0 μm, inclusive.

The substrate upper surface 30s includes trenches 35 arranged next to one another in the transistor region A2. For example, the trenches 35 each extend in the x-direction and are separated from one another in the y-direction. The interval between the trenches 35 (distance between the centers of the trenches 35) in the y-direction is, for example, between 1.5 μm and 7.0 μm, inclusive. Each trench 35 has a width (y-direction dimension of trench 35) of, for example, between 0.5 μm and 3.0 μm, inclusive. Each trench 35 extends through the base region 34 in the z-direction to an intermediate part of the drift layer 33.

The upper surface of the base region 34 (substrate upper surface 30s) includes n⁺-type emitter regions 36 in the transistor region A2. The emitter regions 36 are arranged at opposite sides of each trench 35 with respect to the y-direction. That is, the emitter regions 36 are located in the base region 34 at opposite sides of each trench 35 with respect to the direction in which the trenches 35 are arranged. Therefore, two emitter regions 36, spaced apart from each other in the y-direction, are arranged between the trenches 35 that are adjacent to each other in the y-direction. Each emitter region 36 has a depth of, for example, between 0.2 μm and 0.6 μm, inclusive. Each emitter region 36 has a dopant concentration, which is greater than that of the base region 34, of, for example, between 1×10¹⁹ cm⁻³ and 5×10²⁰ cm⁻³, inclusive.

The upper surface of the base region 34 (substrate upper surface 30s) includes the base contact regions 37, which are of a p⁺-type, in the transistor region A2. Each base contact region 37 is arranged adjacent to the emitter regions 36 in the y-direction. More specifically, each base contact region 37 is located between two emitter regions 36 in the y-direction that are located between trenches 35 that are adjacent to each other in the y-direction. The base contact regions 37 may be formed deeper than the emitter regions 36. Each base contact region 37 has a depth of, for example, between 0.2 μm and 1.6 μm, inclusive. Each base contact region 37 has a dopant concentration, which is greater than that of the base region 34, of, for example, between 5×10¹⁸ cm⁻³ and 1×10²⁰ cm⁻³, inclusive.

A first insulating layer 38 is formed integrally on both the wall surface of each trench 35 and the substrate upper surface 30s. The first insulating layer 38 includes, for example, silicon oxide (SiO₂). The first insulating layer 38 has a thickness of, for example, between 1100 angstroms and 1300 angstroms, inclusive.

An electrode material including, for example, polysilicon, is embedded in each trench 35 via the first insulating layer 38. The electrode material embedded in each trench 35 is electrically connected to the first transistor pad 11 or the second transistor pad 12. More specifically, the electrode material embedded in the trenches 35 forms the gate trenches 23A and emitter trenches 21A. In the present embodiment, the gate trenches 23A and the emitter trenches 21A are alternately arranged in the direction in which the trenches 35 are arranged. In the present embodiment, the gate trenches 23A and the emitter trenches 21A are both filled up to the open end of the corresponding trench 35.

A second insulating layer 39 is formed above the first insulating layer 38, which is arranged on the substrate upper surface 30s. The second insulating layer 39 includes, for example, SiO₂. The first transistor pad 11 is formed above the second insulating layer 39. Therefore, the second insulating layer 39 is an interlayer film filling the gap between the first transistor pad 11 and the gate trenches 23A. Further, the second insulating layer 39 is an interlayer film filling the gap between the first transistor pad 11 and the emitter trenches 21A. The second insulating layer 39 has a thickness between 3000 angstroms and 15000 angstroms, inclusive.

Contact holes 39a extend through both the first insulating layer 38 and the second insulating layer 39 in the z-direction. The contact holes 39a are located at positions overlapping the base contact regions 37 in plan view. The first transistor pad 11 is electrically connected to the base contact regions 37 through the contact holes 39a.

There is no limitation to the gate interconnect electrically connecting the electrode material embedded in the gate trenches 23A to the second transistor pad 12. One example of the gate interconnect in the present embodiment is interconnect formed by the electrode material embedded in and extending from the gate trenches 23A. Further, the gate interconnect may be metal interconnect, such as gate fingers, formed from metal above the second insulating layer 39.

Configuration of the Temperature Sensing Diode

FIG. 4 is a cross-sectional view taken along line 4-4 in FIG. 1 and shows one example of the cross-sectional structure of the semiconductor device 10 in the diode region A1 and the transistor region A2.

The semiconductor device 10 includes a thin polysilicon layer 43 in which the temperature sensing diode 40 is arranged. The polysilicon layer 43 is quadrilateral in plan view. The polysilicon layer 43 is formed above the semiconductor substrate 30. More specifically, a third insulating layer 41 is formed on the upper surface of the base region 34 of the semiconductor substrate 30 in the diode region A1. The third insulating layer 41 includes, for example, SiO₂.

The polysilicon layer 43 is formed on an upper surface 41s of the third insulating layer 41. The third insulating layer 41 is formed integrally with the first insulating layer 38. Therefore, the third insulating layer 41 forms part of the first insulating layer 38. The third insulating layer 41 differs from the first insulating layer 38 in that it insulates the polysilicon layer 43 from the semiconductor substrate 30. Therefore, the first insulating layer 38 and the third insulating layer 41 may be formed separately.

The temperature sensing diode 40 is formed by the polysilicon layer 43. The polysilicon layer 43 includes the first semiconductor region 44P, which is of a first conduction type, and the second semiconductor region 45P, which is of a second conduction type and is bonded to the first semiconductor region 44P. The first conduction type is, for example, the p-type, and the second conduction type is, for example, the n-type. In one example, the temperature sensing diode 40 has a quadrilateral shape in plan view.

The first semiconductor region 44P is doped with a p-type dopant, such as B or Al. The first semiconductor region 44P has a dopant concentration of, for example, between 1×10¹⁸ cm⁻³ and 1×10²⁰ cm⁻³, inclusive. The second semiconductor region 45P is doped with an n-type dopant, such as N, P, or As. The second semiconductor region 45P has a dopant concentration of, for example, between 1×10¹⁸ cm⁻³ and 5×10²⁰ cm⁻³, inclusive.

The polysilicon layer 43 is covered by a fourth insulating layer 42. The fourth insulating layer 42 includes, for example, SiO₂. The first transistor pad 11 is formed above the fourth insulating layer 42. Therefore, the first transistor pad 11 includes a portion formed above the temperature sensing diode 40 such that the fourth insulating layer 42 is sandwiched between the portion and the temperature sensing diode 40. The fourth insulating layer 42 is an interlayer film filling the gap between the first transistor pad 11 and the polysilicon layer 43. The fourth insulating layer 42 is formed integrally with the second insulating layer 39. Therefore, the fourth insulating layer 42 forms part of the second insulating layer 39.

The fourth insulating layer 42 includes an insulating-layer upper surface 42A, which is located above the temperature sensing diode 40 (i.e., the polysilicon layer 43), and insulating-layer side surfaces 42B, which are located beside the polysilicon layer 43 and connect the insulating-layer upper surface 42A to the third insulating layer 41. The insulating-layer upper surface 42A includes, in plan view, a peripheral portion that is at least partially sloped such that the fourth insulating layer 42 gradually decreases in thickness toward the insulating-layer side surfaces 42B.

In one example, the entire peripheral portion of the insulating-layer upper surface 42A in plan view is sloped toward the insulating-layer side surfaces 42B such that the thickness of the fourth insulating layer 42 gradually decreases. The insulating-layer side surfaces 42B may extend in the z-direction or may be sloped continuously from the insulating-layer upper surface 42A toward the edges of the insulating-layer upper surface 42A such that the thickness of the fourth insulating layer 42 decreases gradually.

Embedded interconnect 46 is embedded in the fourth insulating layer 42. The embedded interconnect 46 may be formed from any conductive material including at least one of, for example, titanium (Ti), titanium nitride (TiN), tungsten (W), and cobalt (Co). The embedded interconnect 46 includes anode interconnect 46A and cathode interconnect 46B.

The anode interconnect 46A is electrically connected to the first semiconductor region 44P of the polysilicon layer 43 and is used to deliver current to and from the temperature sensing diode 40. The anode interconnect 46A is embedded in the fourth insulating layer 42 and in the second insulating layer 39 such as to pass through the fourth insulating layer 42 and the second insulating layer 39 and be electrically connected to the anode pad 13A. The anode interconnect 46A includes a lower end contacting the first semiconductor region 44P in the second insulating layer 39. In one example, the anode interconnect 46A includes a plurality of interconnect lines. For example, the anode interconnect 46A includes two to five interconnect lines. In one example, the anode interconnect 46A includes two or more interconnect lines. When the anode interconnect 46A includes two or more interconnect lines, the current density in each interconnect line is lower than when the anode interconnect 46A includes only one interconnect line. Further, deformation of the anode interconnect 46A is limited when the anode interconnect 46A is resist-patterned. The anode interconnect 46A may include only one interconnect line.

The cathode interconnect 46B is electrically connected to the second semiconductor region 45P of the polysilicon layer 43 and used to deliver current to and from the temperature sensing diode 40. The cathode interconnect 46B is embedded in the fourth insulating layer 42 and in the second insulating layer 39 such as to pass through the fourth insulating layer 42 and the second insulating layer 39 and be electrically connected to the cathode pad 13B. The cathode interconnect 46B includes a lower end contacting the second semiconductor region 45P in the second insulating layer 39.

In one example, the cathode interconnect 46B includes a plurality of interconnect lines. For example, the cathode interconnect 46B includes two to five interconnect lines. In one example, the cathode interconnect 46B includes two or more interconnect lines. When the cathode interconnect 46B includes two or more interconnect lines, the current density in each interconnect line is lower than when the cathode interconnect 46B includes one interconnect line. Further, deformation of the cathode interconnect 46B is limited when the cathode interconnect 46B is resist-patterned. The cathode interconnect 46B may include only one interconnect line. The number of interconnect lines in the cathode interconnect 46B may be the same as or different from that in the anode interconnect 46A. In one example, the cathode interconnect 46B includes more interconnect lines than the anode interconnect 46A. In another example, the cathode interconnect 46B includes fewer interconnect lines than the anode interconnect 46A.

As shown in FIG. 2, the anode interconnect 46A connects the temperature sensing diode 40 to the anode pad 13A, which is arranged at a position separated from the temperature sensing diode 40 in plan view. The anode interconnect 46A extends through the transistor region A2, which surrounds the diode region A1 in plan view, from the temperature sensing diode 40 to the anode pad 13A.

In one example, the anode interconnect 46A extends straight in the x-direction toward the device side surface 10a, which is the side close to where the anode pad 13A is formed in the peripheral region B, in plan view. Further, the anode interconnect 46A bends at a right angle in the peripheral region B or in the active region A proximate to the peripheral region B to extend straight in the y-direction and then bends at a right angle in the vicinity of the anode pad 13A to extend to below the anode pad 13A. FIG. 2 shows the interconnect lines of the anode interconnect 46A as a single interconnect line for simplicity of illustration. The interconnect lines of the anode interconnect 46A are arranged in parallel along the broken line representing the anode interconnect 46A in FIG. 2.

The cathode interconnect 46B connects the temperature sensing diode 40 to the cathode pad 13B, which is located at a position separated from the temperature sensing diode 40 in plan view. The cathode interconnect 46B extends through the transistor region A2, which surrounds the diode region A1 in plan view, from the temperature sensing diode 40 to the cathode pad 13B. In one example, the cathode interconnect 46B extends straight in the x-direction toward the device side surface 10a, which is the side close to where the cathode pad 13B is formed in the peripheral region B, in plan view. The cathode interconnect 46B is parallel to the anode interconnect 46A at least at the portion extending through the transistor region A2.

Further, the cathode interconnect 46B bends at a right angle in the peripheral region B or in the active region A proximate to the peripheral region B to extend straight in the y-direction and then bends at a right angle in the vicinity of the cathode pad 13B to extend to below the cathode pad 13B. FIG. 2 shows the interconnect lines of the cathode interconnect 46B as a single interconnect line for simplicity of illustration. The interconnect lines of the cathode interconnect 46B are arranged in parallel along the broken line representing the cathode interconnect 46B in FIG. 2.

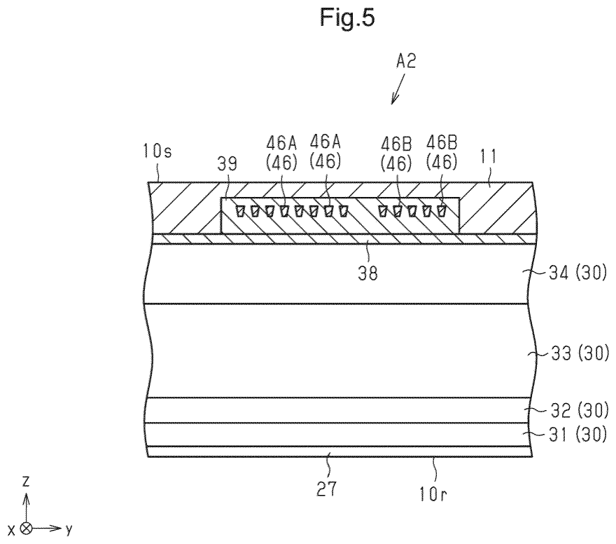

FIG. 5 is a cross-sectional view taken along line 5-5 in FIG. 2 and shows the cross section of the anode interconnect 46A and the cathode interconnect 46B extending through the transistor region A2. As shown in FIG. 5, in the transistor region A2, the anode interconnect 46A and the cathode interconnect 46B are embedded in the second insulating layer 39, which is formed integrally and continuously with the fourth insulating layer 42 of the diode region A1. Further, the anode interconnect 46A and the cathode interconnect 46B respectively extend through the second insulating layer 39 to below the anode pad 13A and below the cathode pad 13B.

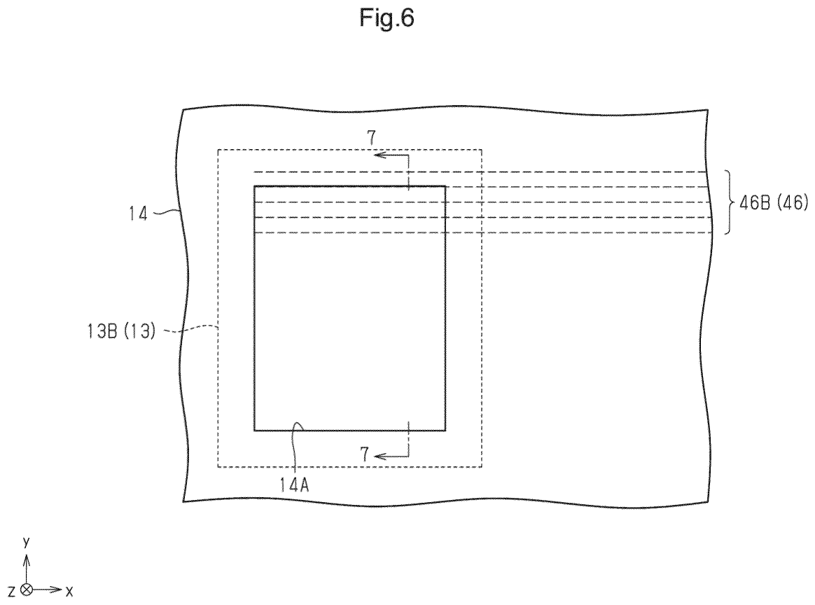

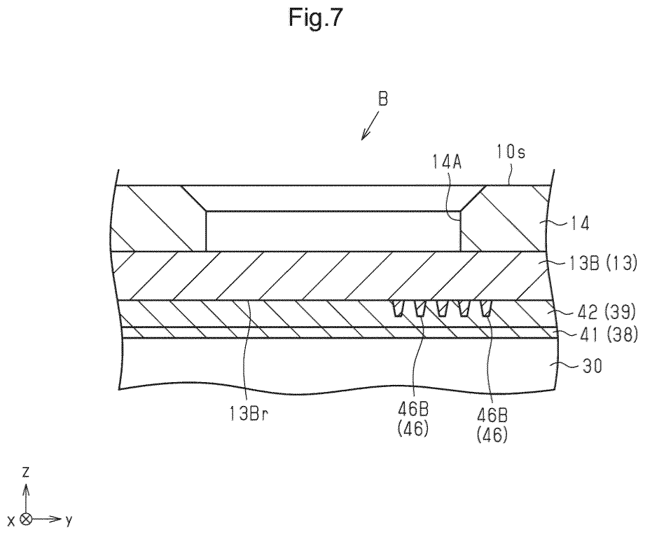

FIG. 6 is an enlarged plan view of the cathode pad 13B in the semiconductor device 10 shown in FIG. 1. FIG. 7 is a cross-sectional view taken along line 7-7 in FIG. 6. As shown in FIG. 6, the cathode interconnect 46B has an end located below the cathode pad 13B. As shown in FIG. 7, the portion of the end of the cathode interconnect 46B located below the cathode pad 13B is in contact with a lower surface 13Br of the cathode pad 13B and electrically connected to the cathode pad 13B. The layout and connecting configuration of the anode pad 13A and the anode interconnect 46A is similar to the layout and connecting configuration of the cathode pad 13B and the cathode interconnect 46B shown in FIGS. 6 and 7. Therefore, the layout and connecting configuration of the anode pad 13A and the anode interconnect 46A will not be described.

### The Conductive Member

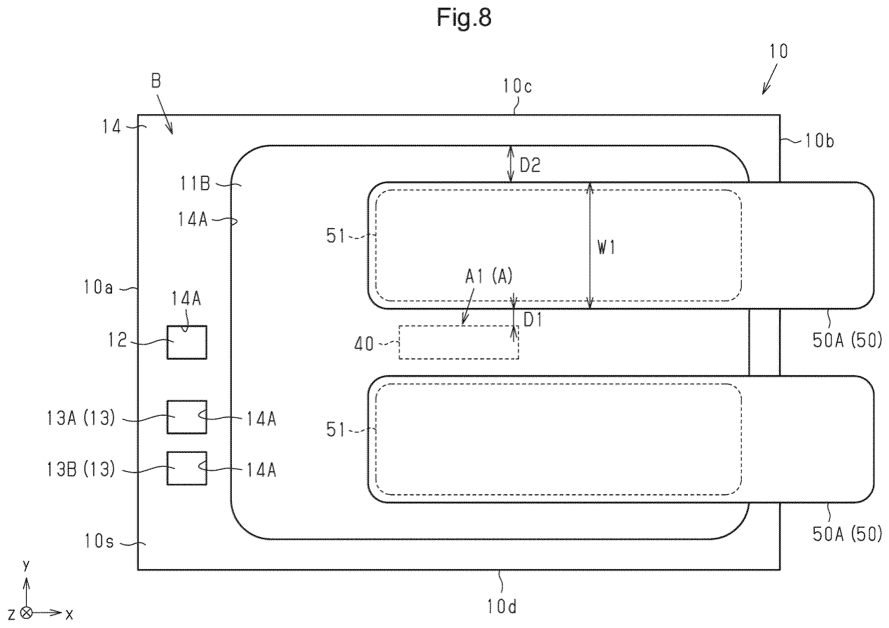

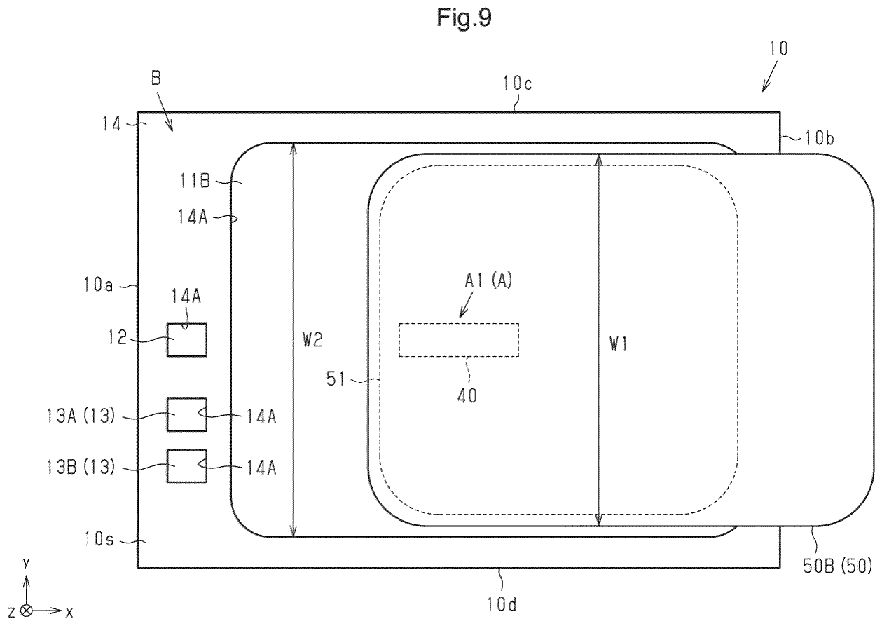

With reference to FIGS. 8 and 9, a plate-shaped conductive member 50 bonded to the first transistor pad 11 will now be described. In the description hereafter, the portion exposed from the opening 14A of the first transistor pad 11 will be described as an emitter electrode 11B.

As shown in FIGS. 8 and 9, the conductive member 50 is bonded to the emitter electrode 11B by an adhesive layer 51. The conductive member 50 is, for example, a metal clip stamped out of a metal sheet. The conductive member 50 is formed from a metal material such as copper (Cu) or aluminum (Al). The adhesive layer 51 is formed from, for example, a conductive bonding material such as solder.

FIG. 8 is a plan view showing one example of a layout in which conductive members 50A are separated from a zone that includes the diode region A1, in which the temperature sensing diode 40 is arranged, and the embedded interconnect 46, connecting the temperature sensing diode 40 to the diode pads 13. In the present example, in order to be separated from the zone described above, the conductive members 50A, which are used as the conductive member 50, have a narrow width W1. Further, to enlarge the area of contact with the emitter electrode 11B, a plurality of conductive members 50A are bonded to the emitter electrode 11B. The conductive members 50A may be branched distal portions of a single conductive member 50.

In the layout example separating the conductive members 50A from the zone described above, the conductive members 50A may be arranged in the vicinity of the diode region A1, For example, as shown in FIG. 8, in plan view, distance D1, which is the shortest distance between a conductive member 50A and the diode region A1, is shorter than distance D2, which is the shortest distance between the conductive member 50A and the edge of the emitter electrode 11B. Distance D1 may be equal to distance D2 or longer than distance D2.

FIG. 9 is a plan view showing one example in which a conductive member 50B is arranged overlapping the diode region A1 in which the temperature sensing diode 40 is arranged. In the present example, to enlarge the area of contact with the emitter electrode 11B, a single conductive member 50B having a large width W1 is used as the conductive member 50. The conductive member 50B is connected to a portion of the first transistor pad 11 that is formed above the temperature sensing diode 40. In one example, the width W1 of the conductive member 50B is less than, but close to, the width W2 of the emitter electrode 11B in the same direction. For example, the width W1 of the conductive member 50B is set so that the difference between width W1 and width W2 (W2−W1) is between 0.4 mm and 1.0 mm, inclusive. This allows a margin between 0.2 mm and 0.5 mm, inclusive, for each of the opposite sides of the conductive member 50B in the direction of the width W1 when the conductive member 50B is arranged on the emitter electrode 11B. One example of the width W1 of the conductive member 50B is at least 50% and less than 100% of the width W2 of the emitter electrode 11B.

### Operation

The operation of the semiconductor device 10 will now be described.

In a semiconductor device that includes an IGBT and a temperature sensing diode, when electrically connecting an electrode pad formed on an upper surface of the semiconductor device to a plate-shaped conductive member, the positioning of the conductive member requires high precision. More specifically, a semiconductor device including an IGBT and a temperature sensing diode uses diode interconnect to connect the temperature sensing diode to a diode pad. To electrically isolate the diode interconnect from the large current for the IGBT, in the related art, an organic protective film is arranged on the diode interconnect, and an electrode pad is formed separated from the organic protective film in plan view. Further, to ensure that there is at least a certain clearance between a conductive member, which is connected to the electrode pad, and the diode interconnect in plan view, the conductive member has to be separated from the diode interconnect and the organic protective film. Therefore, the conductive member has to be positioned with high precision.

In the semiconductor device 10 of the present embodiment, the embedded interconnect 46, which is embedded in the fourth insulating layer 42, forms the diode interconnect that connects the temperature sensing diode 40 to the diode pads 13. The fourth insulating layer 42, which is located above the embedded interconnect 46, electrically isolates the embedded interconnect 46 from the portion where current for the transistor 20 flows. Therefore, the conductive member 50 does not necessarily have to avoid the zone including the diode interconnect and may be arranged close to the zone. This allows the clearance to be reduced or omitted.

Further, the first transistor pad 11 is formed above the temperature sensing diode 40 and above the embedded interconnect 46 such that the first transistor pad 11 sandwiches the fourth insulating layer 42 with the temperature sensing diode 40 and the embedded interconnect 46. This allows for enlargement of the zone in which the first transistor pad 11 is formed on the device upper surface 10s of the semiconductor device 10 in plan view. Therefore, the positioning tolerance of the conductive member 50 can be relaxed. As a result, the conductive member 50 can be positioned relative to the first transistor pad 11 in plan view with a higher degree of freedom.

### Advantages

The semiconductor device 10 has the advantages described below.

(1) The semiconductor device 10 includes the semiconductor substrate 30 including the substrate upper surface 30s and the substrate lower surface 30r opposite the substrate upper surface 30s. The transistor 20 is formed above the substrate upper surface 30s of the semiconductor substrate 30. The temperature sensing diode 40 is formed above the substrate upper surface 30s of the semiconductor substrate 30. The fourth insulating layer 42 is formed above the temperature sensing diode 40. The diode pad 13 is arranged at a position separated from the temperature sensing diode 40, as viewed in a thickness direction of the semiconductor substrate 30. The embedded interconnect 46 is embedded in the fourth insulating layer 42 to connect the temperature sensing diode 40 and the diode pad 13. The first transistor pad 11 is electrically connected to the transistor 20 and includes a portion formed above the temperature sensing diode 40 such that the fourth insulating layer 42 is sandwiched between the portion and the temperature sensing diode 40. As described above in the Operation section, this configuration allows the plate-shaped conductive member 50 to be positioned relative to the first transistor pad 11 in plan view with a higher degree of freedom.

(2) The first transistor pad 11 is formed over the transistor 20 and the temperature sensing diode 40. In this configuration, the first transistor pad 11 is located above the temperature sensing diode 40. This allows for connection of the first transistor pad 11 and the conductive member 50 above the temperature sensing diode 40. Accordingly, the zone in which the conductive member 50 can be arranged is enlarged. Further, the formation of the first transistor pad 11 over a large zone allows the area of contact with the conductive member 50 to be readily enlarged. A large area of contact between the first transistor pad 11 and the conductive member 50 results in the semiconductor device 10 having improved heat dissipation and lower resistance.

(3) The first transistor pad 11 covers the temperature sensing diode 40 entirely, as viewed in the thickness direction of the semiconductor substrate 30. This configuration further enhances advantage (2).

(4) The fourth insulating layer 42 includes the insulating-layer upper surface 42A, located above the temperature sensing diode 40, and the insulating-layer side surfaces 42B, connected to the insulating-layer upper surface 42A. The insulating-layer upper surface 42A includes a peripheral portion that is at least partially sloped such that the fourth insulating layer 42 gradually decreases in thickness toward the insulating-layer side surfaces 42B.

As shown in FIG. 4, the fourth insulating layer 42 arranged above the temperature sensing diode 40 raises the portion of the first transistor pad 11 above the fourth insulating layer 42 by an amount corresponding to the thickness of the fourth insulating layer 42 and forms a projection 11A. If the upper surface of the first transistor pad 11 includes a steep step between the projection 11A and the surrounding portion, when bonding the conductive member 50 with conductive bonding material, the conductive bonding material may enter unintended areas. More specifically, when conductive bonding material, such as solder, is melted above the first transistor pad 11, the conductive bonding material may flow down the step described above. In such a case, the conductive bonding material may enter an unintended area, for example, a position located outside the first transistor pad 11.

In the above configuration, the peripheral portion of the insulating-layer upper surface 42A, that is, the corner at each edge of the fourth insulating layer 42, is sloped gradually. Therefore, the side surfaces of the projection 11A in the first transistor pad 11, which is formed above the fourth insulating layer 42, are also sloped gradually. This reduces the conductive bonding material that flows down the step of the projection 11A. As a result, the conductive bonding material that enters unintended areas is reduced.

### Modified Examples

The above embodiment may be modified as described below. The above embodiment and modified examples described below may be combined as long as there is technical consistency. In the modified examples described hereafter, the same reference characters are given to those components that are the same as the corresponding components of the above embodiment. Such components will not be described in detail.

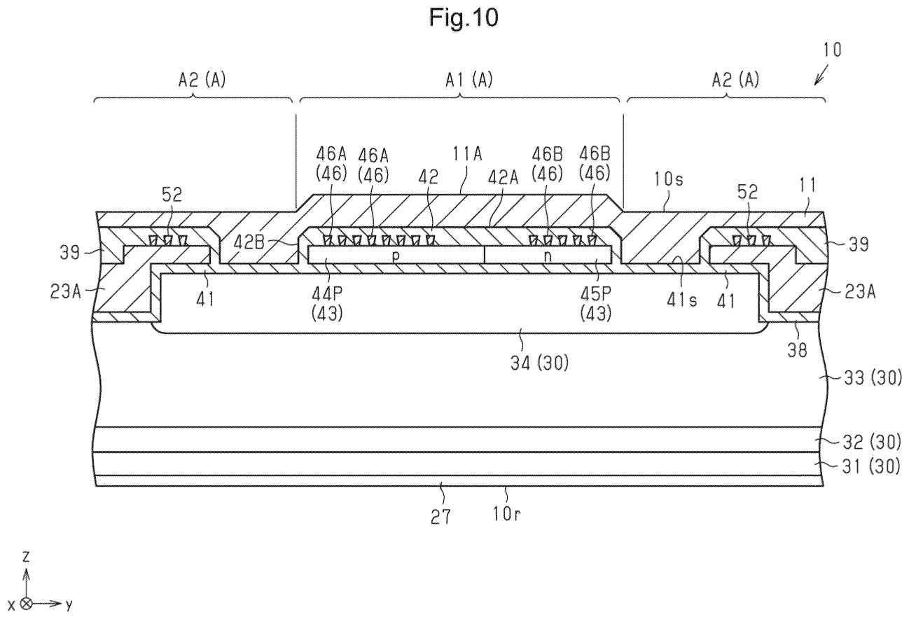

When using metal interconnect, such as gate fingers, as the gate interconnect that electrically connects the electrode material embedded in the gate trenches 23A to the second transistor pad 12, the gate interconnect may be embedded interconnect. FIG. 10 shows such an example.

The semiconductor device 10 shown in FIG. 10 includes embedded interconnect for the transistor 52 embedded in the second insulating layer 39 formed above the gate trenches 23A. The embedded interconnect for the transistor 52 is in contact with the upper surface of the electrode material embedded in the gate trenches 23A. The embedded interconnect for the transistor 52 passes through the second insulating layer 39 and is electrically connected to the second transistor pad 12. In the second insulating layer 39, the embedded interconnect for the transistor 52 is, for example, arranged next to the embedded interconnect 46 (not shown), which connects the temperature sensing diode 40 to the diode pads 13.

When the gate interconnect is the embedded interconnect for the transistor 52, the conductive member 50 can be positioned relative to the first transistor pad 11 with a higher degree of freedom. In this configuration, the second insulating layer 39, which is located above the embedded interconnect for the transistor 52, electrically isolates the embedded interconnect for the transistor 52 from the portion where current for the transistor 20 flows. Therefore, the plate-shaped conductive member 50 does not necessarily have to avoid the zone including the embedded interconnect for the transistor 52 in plan view and may be arranged close to the zone. Accordingly, the plate-shaped conductive member 50 can be positioned relative to the first transistor pad 11 in plan view with a higher degree of freedom.

The protective insulating film 14 may be omitted.

In the above embodiment, the semiconductor device 10 is applied to an IGBT. Instead, the semiconductor device 10 may be applied to a reverse-conducting IGBT, a SiC metal-oxide-semiconductor field-effect transistor (MOSFET), or a Si MOSFET.

In this specification, the word “above” includes the meaning of “on” in addition to the meaning of “above” unless otherwise described in the context. Accordingly, the phrase of “first layer formed above second layer” may mean that the first layer is formed directly contacting the second layer in one embodiment and that the first layer is located above the second layer without contacting the second layer in another embodiment. Thus, the word “above” will also allow for a structure in which another layer is arranged between the first layer and the second layer.

The z-direction referred to in this specification does not necessarily have to be the vertical direction and does not necessarily have to completely coincide with the vertical direction. Accordingly, in the structures of the present disclosure, “up” and “down” in the Z-direction as referred to in this specification is not limited to “up” and “down” in the vertical direction. For example, the x-direction may be the vertical direction. Alternatively, the y-direction may be the vertical direction.

Terms such as “first,” “second,” and “third” in this disclosure are used to distinguish subjects and not used for ordinal purposes.

In this disclosure, “at least one of A and B” should be understood to mean “only A, only B, or both A and B.”

### CLAUSES

Technical concepts that can be understood from each of the above embodiments and modified examples will now be described. Reference characters used in the described embodiment are added to corresponding elements in the clauses to aid understanding without any intention to impose limitations to these elements. The reference characters are given as examples to aid understanding and are not intended to limit elements to the elements denoted by the reference characters.

### Clause 1

A semiconductor device (10), including:
a semiconductor substrate (30) including a substrate upper surface (30s) and a substrate lower surface (30r) opposite the substrate upper surface (30s);
a transistor (20) formed above the substrate upper surface (30s) of the semiconductor substrate (30);
a temperature sensing diode (40) formed above the substrate upper surface (30s) of the semiconductor substrate (30);
an insulating layer (42) formed above the temperature sensing diode (40);
a diode pad (13) arranged at a position separated from the temperature sensing diode (40), as viewed in a thickness direction of the semiconductor substrate (30);
embedded interconnect (46) embedded in the insulating layer (42) to connect the temperature sensing diode (40) and the diode pad (13); and
a first transistor pad (11) electrically connected to the transistor (20) and including a portion formed above the temperature sensing diode (40) such that the insulating layer (42) is sandwiched between the portion and the temperature sensing diode (40).

### Clause 2

The semiconductor device (10) according to clause 1, where the first transistor pad (11) extends over a portion located above the transistor (20) and a portion located above the temperature sensing diode (40).

### Clause 3

The semiconductor device (10) according to clause 1 or 2, where the first transistor pad (11) covers the temperature sensing diode (40) entirely, as viewed in the thickness direction of the semiconductor substrate (30).

### Clause 4

The semiconductor device (10) according to any one of clauses 1 to 3, further including:
an active region (A) located above a central portion of the semiconductor substrate (30), the transistor (20) or the temperature sensing diode (40) being formed in the active region (A), as viewed in the thickness direction of the semiconductor substrate (30); and
a peripheral region (B) surrounding the active region (A) and located above a peripheral portion of the semiconductor substrate (30), as viewed in the thickness direction of the semiconductor substrate (30), where
the first transistor pad (11) is formed in the active region (A), and
the diode pad (13) is formed in the peripheral region (B).

### Clause 5

The semiconductor device (10) according to clause 4, where:
the active region (A) includes
   a diode region (A1) in which the temperature sensing diode (40) is formed, and
   a transistor region (A2) surrounding the diode region (A1), the transistor (20) being formed in the transistor region (A2); and
the embedded interconnect (46) passes through the transistor region (A2) and connects to the diode pad (13).

### Clause 6

The semiconductor device (10) according to any one of clauses 1 to 4, where:
the temperature sensing diode (40) includes a polysilicon layer (43) formed between the substrate upper surface (30s) of the semiconductor substrate (30) and the insulating layer (42);
the polysilicon layer (43) includes, as viewed in the thickness direction of the semiconductor substrate (30), an anode region (44P), doped with a p-type impurity, and a cathode region (45P), doped with an n-type impurity;
the diode pad (13) includes an anode pad (13A) and a cathode pad (13B); and
the embedded interconnect (46) includes
   anode interconnect (46A) connecting the anode region (44P) and the anode pad (13A), and
   cathode interconnect (46B) connecting the cathode region (45P) and the cathode pad (13B).

### Clause 7

The semiconductor device (10) according to any one of clauses 1 to 6, where:
the insulating layer (42) includes an insulating-layer upper surface (42A), located above the temperature sensing diode (40), and an insulating-layer side surface (42B), connected to the insulating-layer upper surface (42A); and
the insulating-layer upper surface (42A) includes a peripheral portion that is at least partially sloped such that the insulating layer (42) gradually decreases in thickness toward the insulating-layer side surface (42B).

### Clause 8

The semiconductor device (10) according to any one of clauses 1 to 7, where:
the insulating layer (39) includes a portion formed above the transistor (20); and
the semiconductor device (10) further includes:
   a second transistor pad (12) arranged at a position separated from the transistor (20), as viewed in the thickness direction of the semiconductor substrate (30); and
   embedded interconnect for the transistor (52) embedded in the insulating layer (39) to connect the transistor (20) and the second transistor pad (12).

### Clause 9

The semiconductor device (10) according to any one of clauses 1 to 8, further including a conductive member (50) that is plate-shaped and connected by an adhesive layer (51) to the first transistor pad (11).

### Clause 10

The semiconductor device (10) according to clause 9, where the conductive member (50) is connected to the first transistor pad (11) at a portion formed above the temperature sensing diode (40).

### Clause 11

The semiconductor device (10) according to clause 9, where the conductive member (50) is connected to the first transistor pad (11) at a portion formed above the embedded interconnect (46).

### Clause 12

The semiconductor device (10) according to any one of clauses 1 to 11, where the first transistor pad (11) includes a portion located above the embedded interconnect (46).

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A semiconductor device, comprising:
a semiconductor substrate including a substrate upper surface and a substrate lower surface opposite the substrate upper surface;
a transistor formed above the substrate upper surface of the semiconductor substrate;
a temperature sensing diode formed above the substrate upper surface of the semiconductor substrate;
an insulating layer formed above the temperature sensing diode;
a diode pad arranged at a position separated from the temperature sensing diode, as viewed in a thickness direction of the semiconductor substrate;
embedded interconnect embedded in the insulating layer to connect the temperature sensing diode and the diode pad; and
a first transistor pad electrically connected to the transistor and including a portion formed above the temperature sensing diode such that the insulating layer is sandwiched between the portion and the temperature sensing diode.

2. The semiconductor device according to claim 1, wherein the first transistor pad extends over a portion located above the transistor and a portion located above the temperature sensing diode.

3. The semiconductor device according to claim 1, wherein the first transistor pad covers the temperature sensing diode entirely, as viewed in the thickness direction of the semiconductor substrate.

4. The semiconductor device according to claim 1, further comprising:
an active region located above a central portion of the semiconductor substrate, the transistor or the temperature sensing diode being formed in the active region, as viewed in the thickness direction of the semiconductor substrate; and
a peripheral region surrounding the active region and located above a peripheral portion of the semiconductor substrate, as viewed in the thickness direction of the semiconductor substrate, wherein
the first transistor pad is formed in the active region, and
the diode pad is formed in the peripheral region.

5. The semiconductor device according to claim 4, wherein:
the active region includes
a diode region in which the temperature sensing diode is formed, and
a transistor region surrounding the diode region, the transistor being formed in the transistor region; and
the embedded interconnect passes through the transistor region and connects to the diode pad.

6. The semiconductor device according to claim 1, wherein:
the temperature sensing diode includes a polysilicon layer formed between the substrate upper surface of the semiconductor substrate and the insulating layer;
the polysilicon layer includes, as viewed in the thickness direction of the semiconductor substrate, an anode region, doped with a p-type impurity, and a cathode region, doped with an n-type impurity;
the diode pad includes an anode pad and a cathode pad; and
the embedded interconnect includes
anode interconnect connecting the anode region and the anode pad, and
cathode interconnect connecting the cathode region and the cathode pad.

7. The semiconductor device according to claim 1, wherein:
the insulating layer includes an insulating-layer upper surface, located above the temperature sensing diode, and an insulating-layer side surface, connected to the insulating-layer upper surface; and
the insulating-layer upper surface includes a peripheral portion that is at least partially sloped such that the insulating layer gradually decreases in thickness toward the insulating-layer side surface.

8. The semiconductor device according to claim 1, wherein:
the insulating layer includes a portion formed above the transistor; and
the semiconductor device further comprises:
a second transistor pad arranged at a position separated from the transistor, as viewed in the thickness direction of the semiconductor substrate; and
embedded interconnect for the transistor embedded in the insulating layer to connect the transistor and the second transistor pad.

9. The semiconductor device according to claim 1, further comprising a conductive member that is plate-shaped and connected by an adhesive layer to the first transistor pad.

10. The semiconductor device according to claim 9, wherein the conductive member is connected to the first transistor pad at a portion formed above the temperature sensing diode.
